(19) United States
(12) Patent Application Publication
(10) Pub. No.: US 2025/0125574 A1
(43) Pub. Date: Apr. 17, 2025

(54) AMPLIFIERS HAVING DISTRIBUTED PUMPING

(71) Applicant: Santec Holdings Corporation, Komaki (JP)

(72) Inventor: Changho Chong, Los Altos, CA (US)

(73) Assignee: Santec Holdings Corporation, Komaki (JP)

(21) Appl. No.: 18/488,130

(22) Filed: Oct. 17, 2023

(51) Int. Cl. H01S 3/094; H01S 3/067; H01S 5/026; H01S 5/183

(52) U.S. Cl. CPC H01S 3/094007; H01S 3/06754; H01S 5/026; H01S 5/18302

(57) ABSTRACT

An apparatus for amplifying light includes a substrate, a cladding formed on the substrate, a gain medium formed inside the cladding, and a pump light source configured to provide a pump light through a plurality of optical paths. A first portion of the gain medium receives a first portion of the pump light through a first optical path, and a second portion of the gain medium receives a second portion of the pump light through a second optical path, the second optical path separate from the first optical path.

### BACKGROUND

The following description is provided to assist the understanding of the reader. None of the information provided or references cited is admitted to be prior art.

Optical fiber amplifiers have improved the reach and distance of the fiber optic communication and compensated the limited power and insertion loss of optical components in transmission lines. For example, Erbium-Doped Fiber Amplifier (EDFA) can be used for C-band wavelength range and widely deployed in current long-haul fiber networks or transponders. Waveguide amplifiers, such as Erbium-Doped Waveguide Amplifier (EDWA), allow for an amplifier design without optical fibers and surrounding functional components.

### SUMMARY

The present technology provides waveguide amplifiers having distributed pumping and methods of using the same.

One aspect of the present disclosure is directed to an apparatus for amplifying light, including a substrate; a cladding formed on the substrate; a gain medium formed inside the cladding; and a pump light source configured to provide a pump light through a plurality of optical paths. A first portion of the gain medium receives a first portion of the pump light through a first optical path, and a second portion of the gain medium receives a second portion of the pump light through a second optical path, the second optical path separate from the first optical path.

In some examples, the apparatus further includes an input portion of the cladding, the input portion configured to receive an input signal; and an output portion of the cladding, the output portion configured to output an amplified signal in response to receipt of the input signal and the pump light.

In some examples, the pump light source is a vertical cavity surface emitting laser (VCSEL).

In some examples, the pump light source is integrated on a chip. In some examples, the apparatus further includes a first aperture formed on the chip, the first aperture defining the first optical path; and a second aperture formed on the chip, the second aperture defining the second optical path.

In some examples, the apparatus further includes a grating coupler optically coupled to the pump light source. The grating coupler includes a first grating portion to direct the first portion of the pump light to the first portion of the gain medium through the first optical path; and a second grating portion to direct the second portion of the pump light to the second portion of the gain medium through the second optical path. In some examples, the apparatus further includes a waveguide structure to accommodate the cladding serving as a waveguide cladding and the gain medium serving as a waveguide core; and a plurality of grating portions formed on the grating coupler, the plurality of grating portions including the first grating portion and the second grating portion. The plurality of grating portions are arranged such that each of the plurality of grating portions is to direct a corresponding portion of the pump light to one or more corresponding portions of the gain medium. In some examples, the gain medium is arranged in a spiral shape.

Another aspect of the present disclosure is directed to an apparatus for amplifying light, including a substrate; a cladding formed on the substrate; a gain medium formed inside the cladding; a first pump light source disposed above a first portion the gain medium; and a second pump light source disposed above a second portion of the gain medium. The first pump light source is configured to project a first pump light onto at least the first portion of the gain medium; and the second pump light source is configured to project a second pump light onto at least the second portion of the gain medium.

In some examples, the first pump light source and the second pump light source are integrated on a chip.

In some examples, the first pump light source and the second pump light source are each a vertical cavity surface emitting laser (VCSEL).

In some examples, the apparatus further includes a reflective layer disposed above or below the gain medium.

In some examples, the apparatus further includes a waveguide structure to accommodate the cladding serving as a waveguide cladding and the gain medium serving as a waveguide core, wherein the gain medium is arranged within the cladding along the waveguide structure; and a plurality of pump light sources, each configured to provide a corresponding pump light to a corresponding portion of the gain medium.

In some examples, a first power level of the first pump light source is different from a second power level of the second pump light source.

In some examples, the apparatus further includes an input portion of the cladding, the input portion configured to receive an input signal; and an output portion of the cladding, the output portion configured to output an amplified signal in response to receipt of the input signal and the pump light. In some examples, the apparatus further includes at least one of: a tunable filter configured to filter the amplified signal having a predetermined wavelength; a photodetector to detect the amplified signal; or an optical component configured to control a polarization state of the input signal or the amplified signal.

Another aspect of the present disclosure is directed to a method for amplifying light. The method includes generating, by a pump light source, a pump light; and directing a first portion of the pump light to a first portion of a gain medium through a first optical path, and directing a second portion of the pump light to a second portion of the gain medium through a second optical path, wherein the first optical path and the second optical path are separate from each other. The gain medium is formed within a cladding of a substrate.

In some examples, the method further includes receiving, by an input portion of the cladding, an input signal; and outputting, by an output portion of the cladding, an amplified signal in response to the receiving of the input signal and the directing of the pump light.

In some examples, the method further includes coupling the pump light to a grating coupler; and directing, by a first grating portion of the grating coupler, the first portion of the pump light to the first portion of the gain medium through the first optical path, and directing, by a second grating portion of the grating coupler, the second portion of the pump light to the second portion of the gain medium through the second optical path.

In some examples, the pump light source is a vertical cavity surface emitting laser (VCSEL) integrated on a chip. The foregoing summary is illustrative only and is not intended to be in any way limiting. In addition to the illustrative aspects, embodiments, and features described above, further aspects, embodiments, and features will become apparent by reference to the following drawings and the detailed description.

### BRIEF DESCRIPTION OF THE DRAWINGS

The foregoing and other features of the present disclosure will become more fully apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings.

FIG. 1 illustrates an example apparatus for amplifying light in accordance with various embodiments.

FIG. 2 illustrates an example apparatus for amplifying light in accordance with various embodiments.

FIG. 3 illustrates example apparatuses for amplifying light in accordance with various embodiments.

FIG. 4A illustrates a perspective view of an example apparatus for amplifying light in accordance with various embodiments.

FIG. 4B illustrates a top view of the example apparatus for amplifying light in accordance with various embodiments.

FIG. 4C illustrates a cross section view (the line L-L′ of FIG. 4B) of the example apparatus in accordance with various embodiments.

FIG. 5 illustrates an example apparatus for amplifying light in accordance with various embodiments.

FIG. 6A illustrates a top view of an example apparatus for amplifying light in accordance with various embodiments.

FIG. 6B illustrates an enlarged side view of a portion of the example apparatus in accordance with various embodiments.

FIG. 7 illustrates a top view of an example apparatus for amplifying light in accordance with various embodiments.

FIG. 8 illustrates a top view of an example apparatus for amplifying light in accordance with various embodiments.

FIG. 9 illustrates a top view of an example apparatus for amplifying light in accordance with various embodiments.

FIG. 10 illustrates a top view of an example apparatus for amplifying light in accordance with various embodiments.

FIG. 11 illustrates a schematic view of an example apparatus for amplifying light in accordance with various embodiments.

FIG. 12 illustrates a schematic view of an example apparatus for amplifying light in accordance with various embodiments.

FIG. 13 is a flow chart of an example method for amplifying light in accordance with various embodiments.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and make part of this disclosure.

Although waveguide amplifiers, such as Erbium-Doped Waveguide Amplifiers (EDWA), have long been researched, they still encounter various challenges. For example, end/edge pumping in waveguide amplifiers generates excessive heat, which causes unstable performance of amplifier components. In addition, gain generation is not uniform throughout the waveguide amplifier. Also, mode matching and optimizing a coupling of different wavelengths are complicated in terms of hybrid or heterogenous integration, while alignment of a pump light source is not manufacturing-robust process or well established. In some cases, when compound semiconductors are used to directly pump the gain medium (e.g., according to a vertical cavity structure arrangement), the transmission bandwidth is limited by a shorter carrier lifetime of the compound semiconductors, thereby preventing a higher modulation frequency bandwidth.

As will be discussed in further detail below, a waveguide amplifier disclosed herein includes distributed pumping. The waveguide amplifier disclosed herein includes a substrate, a cladding formed on the substrate, a gain medium formed inside the cladding, and a pump light source configured to provide a pump light through a plurality of optical paths. A first portion of the gain medium receives a first portion of the pump light through a first optical path, and a second portion of the gain medium receives a second portion of the pump light through a second optical path, the second optical path separate from the first optical path. This allows a signal to be amplified through distributed pumping. The distributed pumping based waveguide amplifier can provide a solution to challenges that the EDWAs are facing. The waveguide amplifier disclosed herein can reduce excessive heat and damages to components, thereby allowing for stable operation of the amplifier. In addition, the waveguide amplifier disclosed herein can provide a uniform pumping distribution, which reduces a noise generated due to uneven gain distribution. Furthermore, The waveguide amplifier disclosed herein allows for a flexible design of the amplifier such that illumination pattern for pumping lights can be designed to match the waveguide layout by changing aperture positions of a light source, such as vertical cavity surface emitting laser (VCSEL), or by having diffractive optical element designed to have arbitrary shaped illumination pattern at the waveguide surface. The power level of individual pumping light can be also adjusted depending on the location of the waveguide(s) and/or the gain medium, thereby forming a multi-stage amplifier. In such a multi-stage amplifier, a noise can be minimized by setting up multiple amplifiers with different amplification levels (e.g., pre-amp, boost-amp stages).

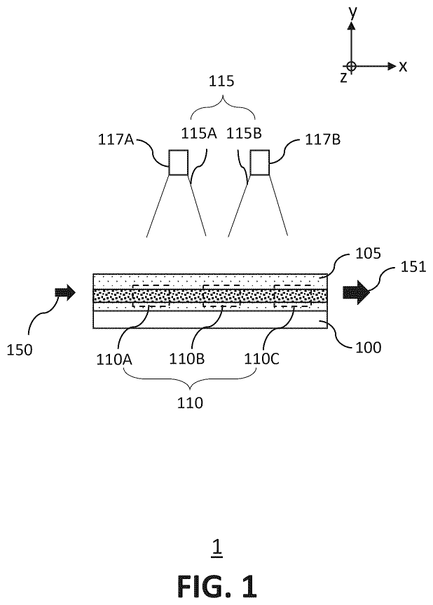

FIG. 1 illustrates an example apparatus 1 for amplifying light in accordance with various embodiments. The apparatus 1 includes a substrate 100, a cladding 105, and a gain medium 110 including a first portion 110A, a second portion 110B, and a third portion 110C. The apparatus 1 can receive an input signal 150, amplify the same, and output an output signal 151. That is, the output signal 151 is an amplified signal of the input signal 150. The apparatus 1 can receive a plurality of pump lights (e.g., a first pump light 115A, a second pump light 115B; collectively referred to as pump lights 115) from a light source to amplify the input signal 150 and generate the output signal 151.

The substrate 100 is a substrate, a wafer, or any structure on which the cladding 105 can be formed. The substrate 100 may be a semiconductor substrate (e.g., a bulk semiconductor, a semiconductor-on-insulator (SOI) substrate, or the like). The substrate 100 may be a semiconductor wafer, such as a silicon wafer. In some examples, the substrate 100 may be a multi-layered or gradient substrate. In some examples, the substrate 100 may be part of a photonic integrated circuit.

The cladding 105 is a dielectric structure formed on the substrate 100. The cladding 105 may be or include SiO₂, Al₂O₃, or any material whose refractive index at the wavelength of the input signal 150 is smaller than the refractive index of the gain medium 110, and/or any material whose absorption is minimized at the wavelength of the input signal 150. In some examples, the cladding 105 and the gain medium 110 can form a waveguide structure with the gain medium 110 serving as a waveguide core.

The gain medium 110 is a structure (e.g., a waveguide core structure) disposed inside the cladding 105. The gain medium 110 may be or include any material that has a non-zero absorption at the wavelength of the pump lights 115 and has a refractive index greater than that of the cladding 105 at the wavelength of the input signal 150. For example, the gain medium 110 may include an erbium-doped or erbium-based gain material. The gain medium 110 can absorb at least a portion of the pump lights 115 and generate a light to amplify the input signal 150. For example, in response to receipt of the pump lights 115, the gain medium 110 can generate a light by spontaneous and stimulated emission at the wavelength of the input signal 150.

The gain medium 110 includes an input portion disposed at one end of the gain medium 110 and an output portion disposed at the other end of the gain medium 110. The input portion of the gain medium 110 can receive the input signal 150. The output portion of the gain medium 110 can output the output signal 151. The output signal 151 can be an amplified signal, amplified when passing through the cladding 105. In some examples, an area proportion of the gain medium 110 that is exposed to the pump lights 115 may range from 40% to 50%.

The apparatus 1 may include a light source that can generate at least a portion of the pump lights 115. The pump lights 115 are lights provided to the gain medium 110. The pump lights 115 include light at a wavelength shorter than the wavelength of the input signal 150, corresponding to the difference between energy levels of the material of the gain medium 110. The pump lights 115 can excite the gain medium 110, which then can generate a light to amplify the input signal 150. Although the pump lights 115 are shown above the gain medium 110, shown is a non-limiting example, and the pump lights 115 can be directed to the gain medium 110 with any angle of incidence. The pump lights 115 can have a plurality of optical paths (e.g., a first optical path 117A, a second optical path 117B, etc.).

In some examples, the pump lights 115 may be generated from a single light source. A single source light generated from the single light source can be split into the first pump light 115A that travels through the first optical path 117A and the second pump light 115B that travels through the second optical path 117B. At least a portion (e.g., the first portion of the gain medium 110A) of the gain medium 110 can receive at least a portion of the first pump light 115A through the first optical path 117A, and at least another portion (e.g., the third portion of the gain medium 110C) of the gain medium 110 can receive at least a portion of the second pump light 115B through the second optical path 117B. As shown, the first optical path 117A and the second optical path 117B are separate from each other. Each portion of the gain medium 110 can receive a pump light through one or more corresponding optical paths. For example, the second portion 110B can receive a pump light from one or more corresponding optical paths (e.g., the first optical path 117A and/or the second optical path 117B), while the third portion 110C can receive a pump light from one or more corresponding optical paths (e.g., the second optical path 117B and/or a third optical path (not shown)).

In some examples, the pump lights 115 may be generated from multiple light sources, each of which has a respective optical path. For example, the first pump light 115A may be from a first light source that directs the first pump light 115A through the first optical path 117A toward at least one of the portions of the gain medium 110 (e.g., the first portion 110A), and the second pump light 115B may be from a second light source that directs the second pump light 115B through the second optical path 117B toward at least one of the portions of the gain medium 110 (e.g., the third portion 110C). Each of the pump lights 115 (or their sources) and/or the optical paths can be provided to at least one corresponding portion of the gain medium 110. For example, the first pump light 115A that travels the first optical path 117A may be directed to one or more corresponding portion of the gain medium 110 (e.g., the first portion 110A and/or the second portion 110B), while the second pump light 115B that travels the second optical path 117B may be directed to one or more corresponding portion of the gain medium 110 (e.g., the second portion 110B and/or the third portion 110C). In some examples, a power level of the first pump light 115A can be adjusted to be different from a power level of the second pump light 115B. In some examples, a power level of the first pump light 115A can be adjusted to be different from a power level of the second pump light 115B depending on a local portion (e.g., 110A, 110B, 110C) of the gain medium 110.

In some examples, the cladding 105, the gain medium 110, and the substrate 100 can form a waveguide structure or a waveguide chip (e.g., Erbium-Doped Waveguide Amplifier (EDWA)). For example, the cladding 105 can serve as a waveguide cladding, and the gain medium 110 can serve as a waveguide core. The waveguide amplifier can receive an input signal through an input portion of the gain medium 110, and can output an amplified signal through an output portion of the gain medium 110. The input signal can be amplified by pumping the gain medium 110. The gain medium 110 can be pumped, for example, by vertically-directed pump lights (e.g., 115).

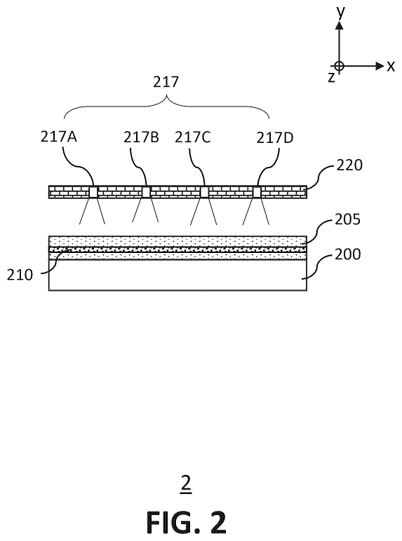

FIG. 2 illustrates an example apparatus 2 for amplifying light in accordance with various embodiments. The apparatus 2 may be substantially similar to and/or incorporate features of the apparatus 1. The apparatus includes a substrate 200, a cladding 205, a gain medium 210, and a chip 220.

The chip 220 includes a light source and can project pump lights through a plurality of optical paths (e.g., a first optical path 217A, a second optical path 217B, a third optical path 217C, a fourth optical path 217D; collectively referred to as optical paths 217) to the gain medium 210. In some examples, the chip 220 can include a plurality of light sources, and each of the plurality of light sources can project a pump light through a respective path of the optical paths 217. In some examples, the chip 220 may include a plurality of apertures or openings, each of which defines the optical paths (e.g., 217A, 217B, 217C, 217D, etc.).

In some examples, the chip 220 can be integrated on the substrate 200 or otherwise coupled to the substrate 200 such that a relative position of the chip 220 is fixed with respect to the gain medium 210. In some examples, a dielectric material can be disposed between the chip 220 and the cladding 205.

In some examples, the chip 220 may include a vertical cavity surface emitting laser (VCSEL) integrated thereon. The VCSEL can project pump lights through the optical paths 217 to the gain medium 210. In some examples, the chip 220 may include a plurality of VCSELs (e.g., an array of VCSELs), each of which can project a pump light through a respective path of the optical paths 217.

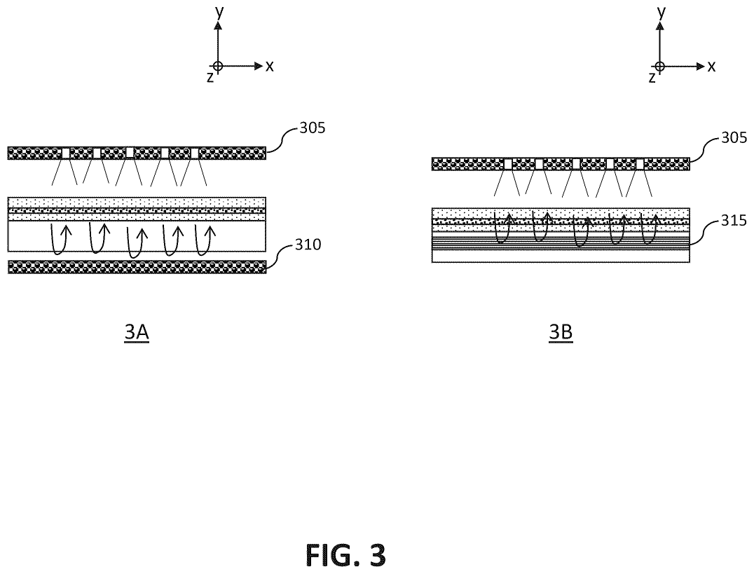

FIG. 3 illustrates example apparatuses 3A and 3B for amplifying light in accordance with various embodiments. The apparatuses 3A and 3B may be substantially similar to and/or incorporate features of the apparatus 1. The apparatuses 3A and 3B can include one or more reflective layers (e.g., 305, 310, 315, etc.).

The apparatus 3A can include the reflective layer 305 disposed above the gain medium. The reflective layer 305 may be a mirror, a reflective layer formed on or a material coated on the surface of a light source chip (e.g., 220), or any material or structure that can reflect a light having a wavelength of the pump lights. The reflective layer 305 can reflect any light reflected from any of the cladding, the gain medium, the substrate, another reflective layer (e.g., the reflective layer 310, the reflective layer 315), etc., thereby re-directing the light into the gain medium and improving amplifying efficiency. In some examples, the reflective layer 305 may be or include a distributed Bragg reflector (DBR), a reflective grating, a dielectric mirror, etc.

The apparatus 3A can include the reflective layer 310 disposed below the gain medium. The reflective layer 310 may be a mirror, a reflective layer formed on or a material coated on the bottom surface of the substrate, or any material or structure that can reflect a light having a wavelength of the pump lights. The reflective layer 310 can reflect any light transmitted through any of the cladding, the gain medium, the substrate, etc., thereby re-directing the light into the gain medium and improving amplifying efficiency. In some examples, the reflective layer 310 may be or include a DBR, a reflective grating, a dielectric mirror, etc.

The apparatus 3B can include the reflective layer 315 disposed inside the substrate. The reflective layer 315 may be a mirror, a reflective layer or a material formed inside the substrate, or any material or structure that can reflect a light having a wavelength of the pump lights. The reflective layer 315 can reflect any light transmitted through any of the cladding, the gain medium, the substrate, etc., thereby re-directing the light into the gain medium and improving amplifying efficiency. In some examples, the reflective layer 315 may be or include a DBR, a reflective grating, a dielectric mirror, etc.

The reflective layer 305, the reflective layer 310, and the reflective layer 315 allow a pump light to travel through multiple paths through the gain medium, thereby increasing the efficiency of gain conversion.

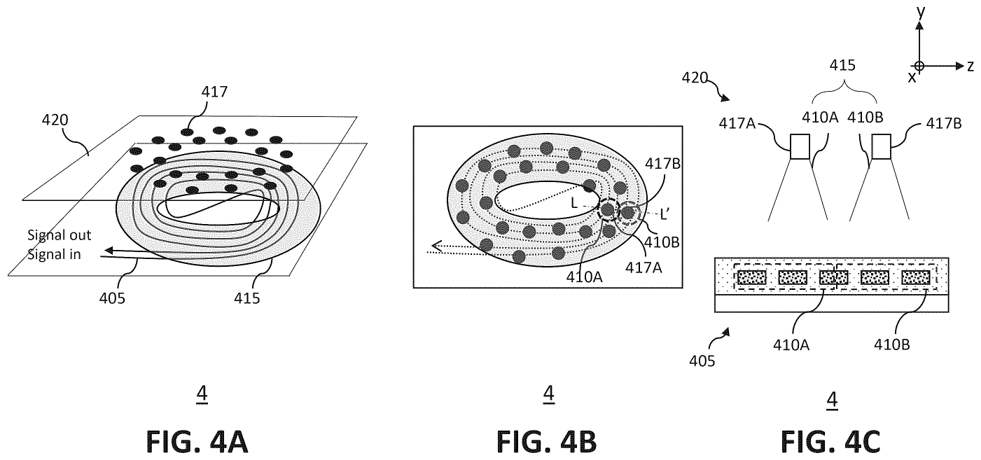

FIG. 4A illustrates a perspective view of an example apparatus 4 for amplifying light in accordance with various embodiments. FIG. 4B illustrates a top view of the example apparatus 4 for amplifying light in accordance with various embodiments. FIG. 4C illustrates a cross section view (the line L-L′ of FIG. 4B) of the example apparatus 4 in accordance with various embodiments. The apparatus 4 may be substantially similar to and/or incorporate features of the apparatus 1. The apparatus 4 includes a waveguide structure 405. The waveguide structure 405 includes a cladding (e.g., 105) extending along the waveguide structure 405. The waveguide structure 405 includes a gain medium (e.g., 110) serving as a waveguide core formed inside the cladding. For example, the waveguide structure 405 may be or include an erbium doped waveguide amplifier (EDWA) or a chip including the same. The waveguide structure 405 (and the cladding and the gain medium) can be in any shape. A non-limiting example of the shape of the waveguide structure 405 may be a spiral shape as shown in FIG. 4A and FIG. 4B.

The apparatus 4 includes a chip 420. The chip 420 can provide pump lights 415 to the waveguide structure 405 through a plurality of apertures 417 (e.g., 417A, 417B). In some examples, the chip 420 can include a single light source to provide the pump lights 415 through the apertures 417 to direct each portion of the pump lights 415 to the respective portion of the gain medium formed inside the waveguide structure 405. More specifically, a first portion of the pump lights 415 can be directed, through a first aperture 417A, to a first area 410A where at least a first portion of the gain medium is formed, and a second portion of the pump lights 415 can be directed, through a second aperture 417B, to a second area 410B where at least a second portion of the gain medium is formed. In some examples, the chip 420 can include a plurality of light sources, which can collectively provide the pump lights 415 through the apertures 417. For example, each of the light sources can have a corresponding aperture to direct the light to the respective portion of the gain medium formed inside the waveguide structure 405. For example, a first light source can provide a first pump light, through the first aperture 417A, to the first area 410A, and a second light source can provide a second pump light, through the second aperture 417B, to the second area 410B. As shown, the apertures 417 can be arranged such that the pump lights 415 projected through the apertures 417 cover the gain medium formed in the waveguide structure 405.

In some examples, the light source of the chip 420 may be or include a VCSEL that can provide the pump lights 415 through the apertures 417. In some examples, the light source of the chip 420 may be or include a plurality of VCSELs (e.g., an array or arrays of VCSELs, any arrangement of VCSELs, etc.) that can provide the pump lights 415 through the apertures 417. In some examples, a plurality of VCSELs may be integrated on a chip. In some examples, a VCSEL may be a VCSEL chip with multiple apertures. For example, the VCSEL chip can operate at a wavelength of 975 nm with 160 mW, including a plurality of apertures (e.g., 20 apertures).

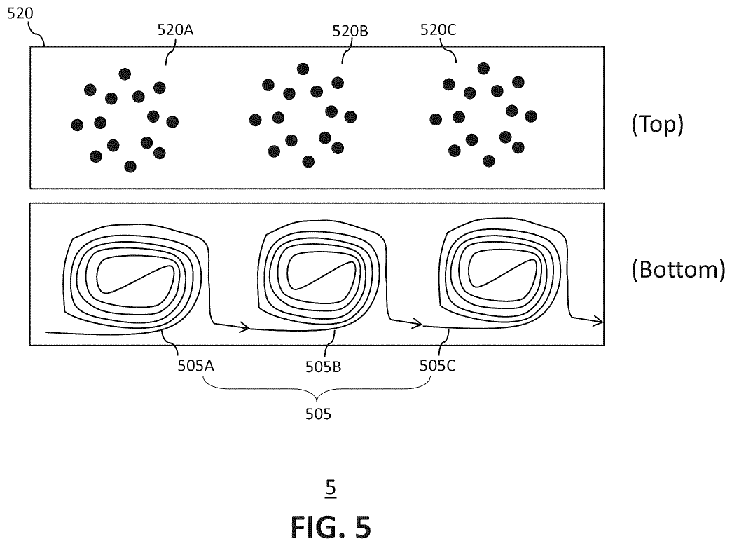

FIG. 5 illustrates an example apparatus 5 for amplifying light in accordance with various embodiments. The apparatus 5 includes a waveguide structure 505 and a chip 520. The waveguide structure 505 includes a cladding (e.g., 105) extending along the waveguide structure 505. The waveguide structure 505 includes a gain medium (e.g., 110) formed inside the cladding. For example, the waveguide structure 505 may be or include an erbium doped waveguide amplifier (EDWA) or a chip including the same. For simplicity and clarity, a top view of each of the waveguide structure 505 and the chip 520 is shown separately. It should be understood that the chip 520 is a top portion of the apparatus 5 and the waveguide structure 505 is a bottom portion of the apparatus 5 such that the chip 520 and the waveguide structure 505 are operably aligned.

The apparatus 5 may be or include any number of amplifiers including a first amplifier (e.g., a first waveguide structure 505A and a first chip portion 520A), a second amplifier (e.g., a second waveguide structure 505B and a second chip portion 520B), and a third amplifier (e.g., a third waveguide structure 505C and a third chip portion 520C). Although three amplifiers are shown in FIG. 5, the apparatus 5 may include any number of amplifiers.

Each of the first waveguide structure 505A, the second waveguide structure 505B, and the third waveguide structure 505C (collectively referred to as the waveguide structure 505) may be substantially similar to and/or incorporate features of the waveguide structure 405 of the apparatus 4. Each of the waveguide structure 505 can be optically coupled. For example, the waveguide structure 505 can include a plurality of waveguide structures optically coupled in series or in parallel. As shown, an output portion of the first waveguide structure 505A can be optically coupled to an input portion of the second waveguide structure 505B, and an output portion of the second waveguide structure 505B can be optically coupled to an input portion of the third waveguide structure 505C. That is, the waveguide structure 505 can receive an input signal through the input portion of the first waveguide structure 505A, and the output portion of the first waveguide structure 505A can output a first amplified signal to the second waveguide structure 505B. The second waveguide structure 505B can receive the first amplified signal and output a second amplified signal to the third waveguide structure 505C. The third waveguide structure 505C can receive the second amplified signal and output a third amplified signal through the output portion of the third waveguide structure 505C.

The chip 520 includes the first chip portion 520A, the second chip portion 520B, and the third chip portion 520C. Each of the first chip portion 520A, the second chip portion 520B, and the third chip portion 520C may be substantially similar to and/or incorporate features of the chip 420 of the apparatus 4. Each of the first chip portion 520A, the second chip portion 520B, and the third chip portion 520C can be formed in a separate chip.

In some examples, the apparatus 5 may be a multi-stage amplifier, including the first amplifier (e.g., the first waveguide structure 505A and the first chip portion 520A), the second amplifier (e.g., the second waveguide structure 505B and the second chip portion 520B), and the third amplifier (e.g., the third waveguide structure 505C and the third chip portion 520C). Each of the multi-stage amplifier can amplify a light with a different power level. For example, the first amplifier is a first pre-amplifier with an amplifying power of 100 mW, the second amplifier is a second pre-amplifier with an amplifying power of 150 mW, and the third amplifier is a power-amplifier with an amplifying power of 200 mW. Shown in FIG. 5 is a non-limiting example, and the apparatus 5 can include any number of pre-amplifiers and/or any number of power-amplifiers with any arrangement thereof. The multi-stage amplifier allows for improved noise control of the amplified signal.

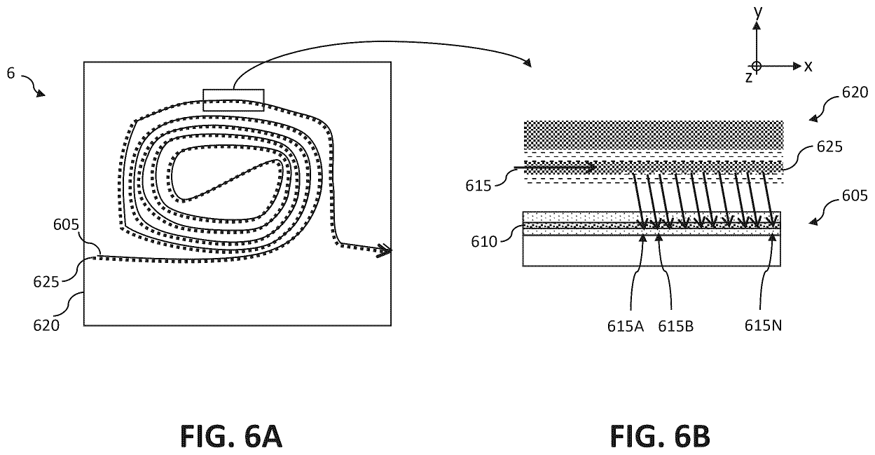

FIG. 6A illustrates a top view of an example apparatus 6 for amplifying light in accordance with various embodiments. FIG. 6B illustrates an enlarged side view of a portion of the example apparatus 6 in accordance with various embodiments. The apparatus 6 may be substantially similar to and/or incorporate features of the apparatus 1. The apparatus 6 includes a waveguide structure 605 (solid line in FIG. 6A) and a chip 520. The waveguide structure 605 includes a cladding (e.g., 105) extending along the waveguide structure 605. The waveguide structure 605 includes a gain medium (e.g., 110) formed inside the cladding. For example, the waveguide structure 605 may be or include an erbium doped waveguide amplifier (EDWA) or a chip including the same. The chip 620 includes a grating coupler 625 (dotted line in FIG. 6A). For simplicity and clarity, in FIG. 6A, the waveguide structure 605 is depicted to be shifted and not to overlap with the grating coupler 625, but if should be understood that the waveguide structure 605 is disposed below the chip 620, as shown in FIG. 6B.

The chip 620 can include the grating coupler 625 in a bottom portion of the chip 620, or a portion where the waveguide structure 605 is located. The grating coupler 625 may be a nanostructure formed of any material, the nanostructure configured to receive a pump light 615 and direct the same to the waveguide structure 605. The grating coupler 625 can receive the pump light 615 from a light source, or otherwise optically coupled to a light source. The grating coupler 625 can direct the pump light 615 into different portions of the gain medium 610. As shown, the grating coupler 625 can direct a first portion of the pump light 615A into a first portion of the gain medium 610, the grating coupler 625 can direct a second portion of the pump light 615B into a second portion of the gain medium 610, and the grating coupler 625 can direct a N-th portion of the pump light 615N into a N-th portion of the gain medium 610. A period, a thickness, a fill factor, etc. of the grating coupler 625 can be designed to direct each portion of the pump light 615 into each corresponding portion of the waveguide structure 605 at a predetermined angle, at a predetermined portion of the grating coupler 625.

In some examples, the gain medium 610 can be formed along the longitudinal direction (e.g., x-axis) of the waveguide structure 605, for example, in a spiral shape as shown in FIG. 6A. The grating coupler 625 can be formed above the waveguide structure 605, along the same path as the gain medium 610, such that each portion of the pump light 615 can be directed into each corresponding portion of the waveguide structure 605. For example, the grating coupler 625 and the gain medium 610 can be formed along the same path such that the grating coupler 625 covers all the length of the gain medium 610.

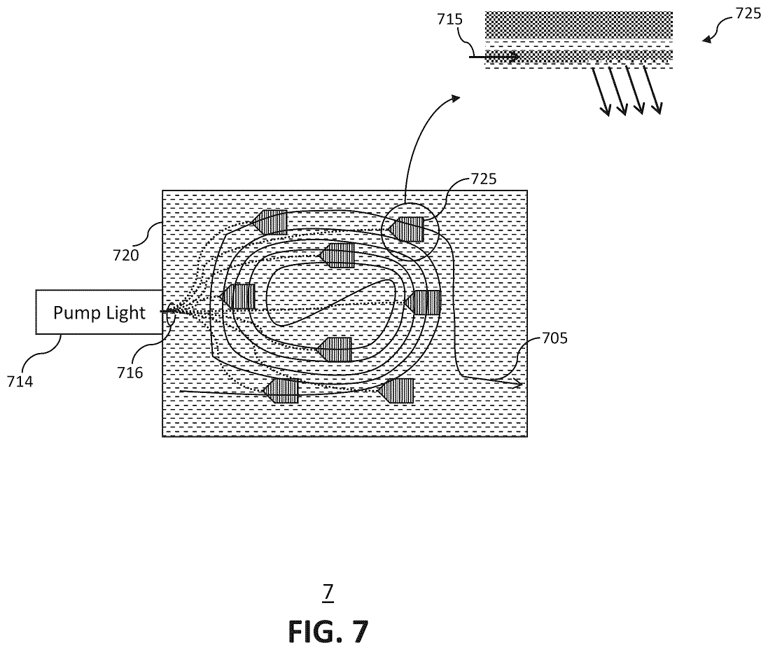

FIG. 7 illustrates a top view of an example apparatus 7 for amplifying light in accordance with various embodiments. The apparatus 7 may be substantially similar to and/or incorporate features of the apparatus 1. The apparatus 7 includes a waveguide structure 705 (solid line) and a chip 720. The waveguide structure 705 includes a cladding (e.g., 105) extending along the waveguide structure 705. The waveguide structure 705 includes a gain medium (e.g., 110) formed inside the cladding. For example, the waveguide structure 705 may be or include an erbium doped waveguide amplifier (EDWA) or a chip including the same. The waveguide structure 705 is disposed below the chip 720, which can provide a pump light 715 to the waveguide structure 705. In some examples, the waveguide structure 705 may be disposed above the chip 720, and the chip 720 can provide the pump light 715 from the below of the waveguide structure 705.

The chip 720 includes a grating coupler 725. As shown in an enlarged view, the grating coupler 725 may be substantially similar or identical to the grating coupler 625. The chip 720 includes a pump light source 714 and a pump supply path 716 (dotted line). The pump light source 714 can be any light source (e.g., a pump laser diode) configured to supply the pump light 715 at a wavelength shorter than the wavelength of the input signal corresponding to the difference between energy levels of the material of the gain medium in the waveguide structure 705. The pump light source 714 can provide the pump light 715, through the pump supply path 716, to the grating coupler 725. The pump supply path 716 can be any structure and/or material integrated on the chip 720 to define an optical path (e.g., a waveguide, a photonic crystal, etc.). The grating coupler 725 can receive the pump light 715 and direct the pump light 715 into different portions (e.g., respective portions of the gain medium) of the waveguide structure 705. As shown in FIG. 7, a plurality of the grating couplers 725 can be nested to direct a portion of the pump light 715 to a respective portion of the gain medium of the waveguide structure 705. The nested grating couplers 725 can direct a portion of the pump light 715 to a plurality of portions of the gain medium of the waveguide structure 705. For example, as shown in FIG. 7, some portions of the waveguide structure 705 share a grating coupler of the nested grating couplers 725.

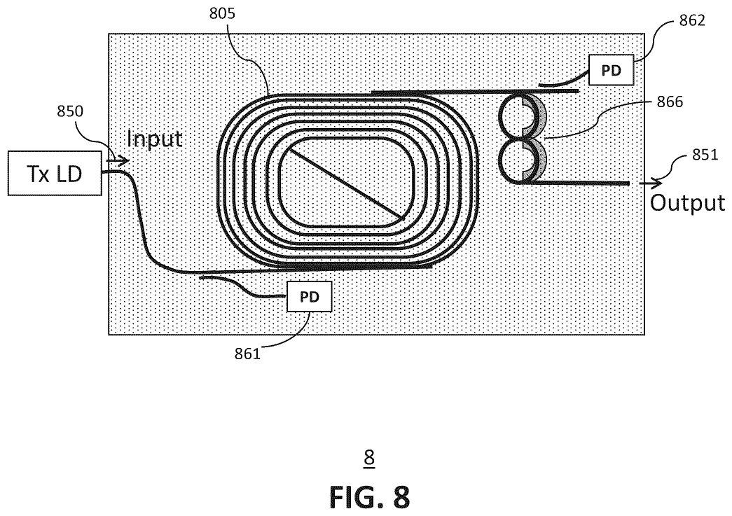

FIG. 8 illustrates a top view of an example apparatus 8 for amplifying light in accordance with various embodiments. The apparatus 8 may be substantially similar to and/or incorporate features of the apparatus 1. The apparatus 8 includes a waveguide structure 805. The waveguide structure 805 includes a cladding (e.g., 105) extending along the waveguide structure 805. The waveguide structure 805 includes a gain medium (e.g., 110) formed inside the cladding. For example, the waveguide structure 805 may be or include an erbium doped waveguide amplifier (EDWA) or a chip including the same. The apparatus 8 includes a chip (e.g., 220) disposed above/below the waveguide structure 805 and configured to provide a pump light to the waveguide structure 805. In some examples, the waveguide structure 805 and the chip can be integrated on a chip or a circuit (e.g., a photonic integrated circuit). The apparatus 8 can include any optical components integrated on such a chip or a circuit.

In some examples, the apparatus 8 can include a first photodetector 861 and a second photodetector 862. The apparatus 8 can receive an input signal 850, amplify the input signal 850, and output an output signal 851. The first photodetector 861 and the second photodetector 862 can be optically coupled to the waveguide structure 805 at various portions thereof to monitor the input signal 850 and/or the amplified signal. In some examples, the first photodetector 861 can be optically coupled to the waveguide structure 805 at an input side of the waveguide structure 805 and detect a portion of the input signal 850 (e.g., the input signal 850 before entering the gain region). The second photodetector 862 can be optically coupled to the waveguide structure 805 at an output side of the waveguide structure 805 and detect a portion of the amplified signal (e.g., the amplified signal to be output, the output signal 851). The difference between a reading from the first photodetector 861 and a reading from the second photodetector 862 allows for a determination of the gain (e.g., amplified by the waveguide structure 805). In some examples, the gain can be controlled based on the detected difference in readings between the first photodetector 861 and the second photodetector 862. For example, the first photodetector 861 and the second photodetector 862 can be an in-line power monitor. In some examples, the first photodetector 861 and the second photodetector 862 can be integrated on a chip or a photonic integrated circuit.

In some examples, the apparatus 8 can include a tunable filter 866 (e.g., a tunable micro-ring resonator). The apparatus 8 can output the output signal 851 through the tunable filter 866. The tunable filter 866 can filter out a portion of the amplified signal (e.g., the portion of the amplified signal at an unwanted wavelength or at a predetermined wavelength, a noise, etc.). For example, the tunable filter 866 can reduce a noise (e.g., amplified spontaneous emission noise). In some examples, the tunable filter 866 and the second photodetector 862 can be optically coupled. The filtering wavelength of the tunable filter 866 can be controlled based on a reading from the second photodetector 862. In some examples, the tunable filter 866 can be integrated on a chip or a photonic integrated circuit.

In some examples, the apparatus 8 can include an optical component configured to control a polarization state of the signal. For example, the apparatus 8 can include a polarization beam splitter, a polarization rotator, etc.

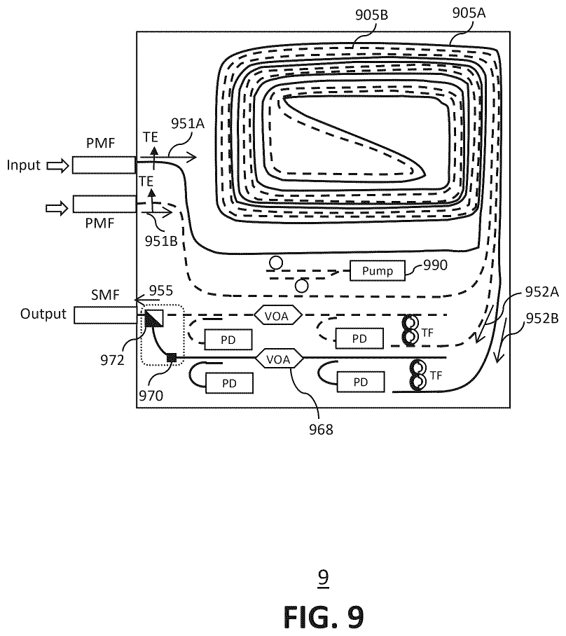

FIG. 9 illustrates a top view of an example apparatus 9 for amplifying light in accordance with various embodiments. The apparatus 9 may be substantially similar to and/or incorporate features of the apparatus 1. The apparatus 9 includes a first waveguide structure 905A, a second waveguide structure 905B, and various optical components to output amplified signals having different polarization states to multiplex two signal inputs. The first waveguide structure 905A and the second waveguide structure 905B can each include a cladding (e.g., 105) and a gain medium (e.g., 110). The first waveguide structure 905A and the second waveguide structure 905B are optically coupled in parallel.

The first waveguide structure 905A can receive a first input signal 951A having a first polarization state (e.g., TE) through an input portion of the first waveguide structure 905A, and the second waveguide structure 905B can receive a second input signal 951B having the first polarization state (e.g., TE) through an input portion of the second waveguide structure 905B. In some examples, the input signals 951A, 951B can be provided to the waveguide structures 905A, 905B respectively, through a polarization maintaining fiber (PMF). The waveguide structures 905A, 905B can output amplified signals 952A, 952B (collectively referred to as 952), respectively.

The waveguide structures 905A, 905B can receive a pump light to amplify the input signals. In some examples, as discussed with respect to FIG. 1 to FIG. 9, the waveguide structures 905A, 905B can receive a pump light (e.g., 115) from a light source (e.g., a VCSEL with a plurality of apertures) or a plurality of light sources (e.g., VCSELs) arranged along the waveguide structures 905A, 905B. In some other examples, the waveguide structures 905A, 905B can receive a pump light in various ways (e.g., without receiving the pump light 115). For example, as shown in FIG. 9, the waveguide structures 905A, 905B can receive a pump light from a pump light source 990 that is optically coupled to an input portion of the waveguide structures 905A, 905B.

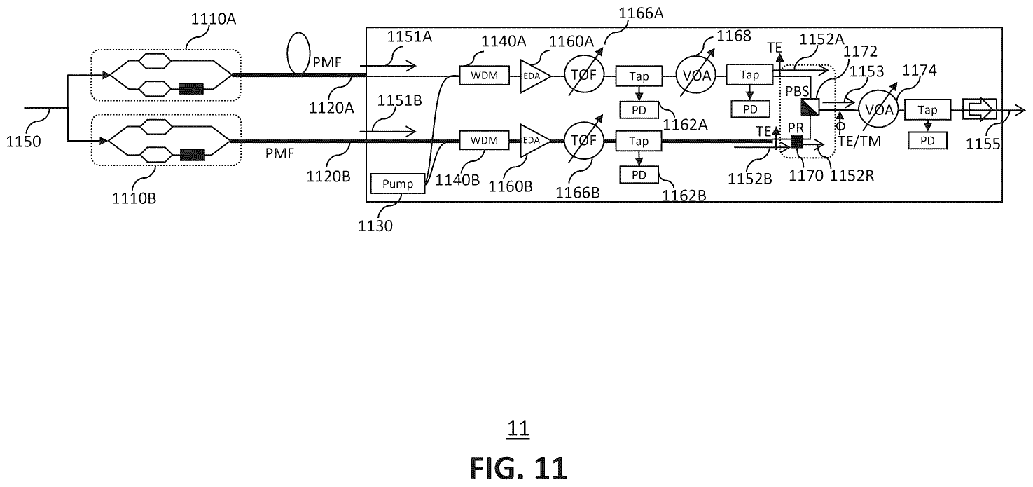

The apparatus 9 includes control components to control properties of the amplified signals 952. The apparatus 9 can include photo detectors (e.g., 862) and tunable filters (e.g., 866). The apparatus 9 can include a variable optical attenuator (VOA) 968. The VOA 968 can attenuate a power level of the amplified signals 952. The apparatus 9 can include a polarization rotator 970 and a polarization beam splitter (PBS) 972 to control polarization states of an output signal 955. As shown, the polarization rotator 970 and the PBS 972 are optically coupled to an output portion of the second waveguide structure 905B. The polarization rotator 970 can rotate the polarization state of the amplified signal 952B (e.g., TE to TM), and the PBS 972 can combine the two amplified signals (e.g., 952A, 952B) into the output signal 955 (e.g., having two orthogonal polarization states). This allows for multiplexing of two amplified signals without polarization-dependent amplification. The controlling of polarization states will be discussed in greater detail with respect to FIG. 11.

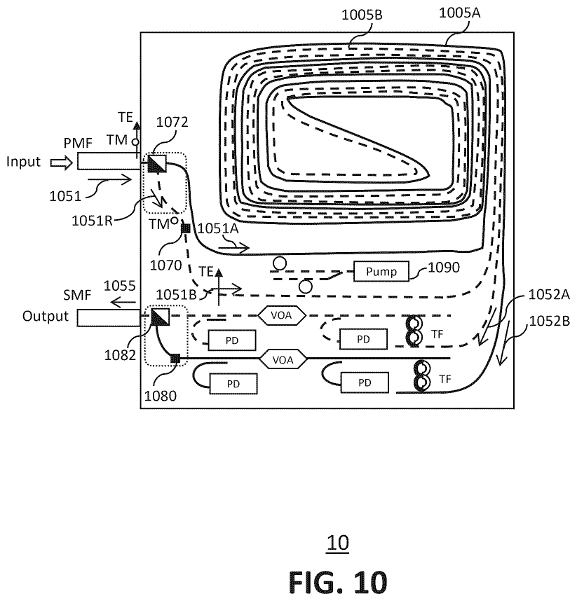

FIG. 10 illustrates a top view of an example apparatus 10 for amplifying light in accordance with various embodiments. The apparatus 10 may be substantially similar to and/or incorporate features of the apparatus 1 and/or the apparatus 9. The apparatus 10 includes a first waveguide structure 1005A, a second waveguide structure 1005B, and various optical components to output amplified signals having different polarization states to multiplex two signal inputs. The first waveguide structure 1005A and the second waveguide structure 1005B are optically coupled in parallel.

The apparatus 10 can receive an input signal 1051 having a first polarization state (e.g., TE) and a second polarization state (e.g., TM). A PBS 1072 can split the input signal 1051 into a first signal 1051A having the first polarization state (e.g., TE), which travels to the first waveguide structure 1005A, and a second input signal 1051R having the second polarization state (e.g., TM), which travels to the second waveguide structure 1005B through a polarization rotator 1070. The polarization rotator 1070 can change a polarization state of the second input signal 1051R, from the second polarization state (e.g., TM) to the first polarization state (e.g., TE). The second input signal 1051R that passes through the polarization rotator 1070 is referred to as a second signal 1051B, which travels to the second waveguide structure 1005B.

The first waveguide structure 1005A can receive the first signal 1051A having the first polarization state (e.g., TE), and the second waveguide structure 1005B can receive the second signal 1051B having the first polarization state (e.g., TE). The waveguide structures 1005A, 1005B can output amplified signals 1052A, 1052B (collectively referred to as 1052), respectively.

The waveguide structures 1005A, 1005B can receive a pump light to amplify the input signals. In some examples, as discussed with respect to FIG. 1 to FIG. 9, the waveguide structures 1005A, 1005B can receive a pump light (e.g., 115) from a light source (e.g., a VCSEL with a plurality of apertures) or a plurality of light sources (e.g., VCSELs) arranged along the waveguide structures 1005A, 1005B. In some other examples, the waveguide structures 1005A, 1005B can receive a pump light in various ways (e.g., without receiving the pump light 115). For example, as shown in FIG. 10, the waveguide structures 1005A, 1005B can receive a pump light from a pump light source 1090 that is optically coupled to an input portion of the waveguide structures 1005A, 1005B.

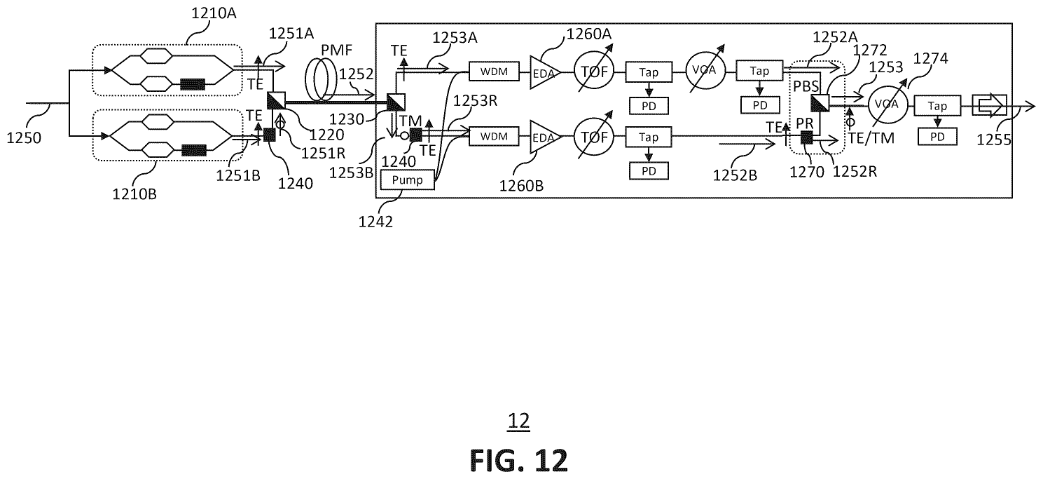

The apparatus 10 includes control components to control properties of the amplified signals 1052. The apparatus 10 can include photo detectors (e.g., 862) and tunable filters (e.g., 866). The apparatus 10 can include a variable optical attenuator (VOA) (e.g., 968). The VOA can attenuate a power level of the amplified signals 1052. The apparatus 10 can include a polarization rotator 1080 and a polarization beam splitter (PBS) 1082 to control the polarization states of an output signal 1055. As shown, the polarization rotator 1080 and the PBS 1082 are optically coupled to an output portion of the second waveguide structure 1005B. The polarization rotator 1080 can rotate the polarization state of the amplified signal 1052B (e.g., TE to TM), and the PBS 1082 can combine the two amplified signals (e.g., 1052A, 1052B) into the output signal 1055 (e.g., having two orthogonal polarization states). This allows for multiplexing of two amplified signals without polarization-dependent amplification. The controlling of the polarization states will be discussed in greater detail with respect to FIG. 12.

FIG. 11 illustrates a schematic view of an example apparatus 11 for amplifying light in accordance with various embodiments. More specifically, the apparatus 11 is an apparatus in which waveguide amplifiers (e.g., the apparatus 1, waveguide structures, EDWA, etc.) are optically coupled in parallel to multiplex two signals having different polarization states (e.g., output amplified lights in different polarization states). The apparatus 11 can receive an input signal 1150, amplify the input signal 1150, and output an output signal 1155 having more than one polarization states. As shown, the apparatus 11 includes a first path (top) including a first waveguide amplifier 1160A and a second path (bottom) including a second waveguide amplifier 1160B, and signals traveling each of the paths can be individually controlled to generate the output signal 1155.

The apparatus 11 includes a first modulator 1110A and a second modulator 11101B (collectively referred to as modulators 1110). The modulators 1110 may be or include an in-phase quadrature-phase (IQ) modulator configured to modulate and/or encode information on the input signal 1150. The first modulator 1110A can receive a first portion of the input signal 1150 and provide a first signal 1151A to the first waveguide amplifier 1160A (e.g., the apparatus 1, waveguide structures, EDWA, etc.) through a first WDM filter 1140A and a first polarization maintaining fiber 1120A. The second modulator 1110B can receive a second portion of the input signal 1150 and provide a second signal 1151B to the second waveguide amplifier 1160B (e.g., the apparatus 1, waveguide structures, EDWA, etc.) through a second WDM filter 1140B and a second polarization maintaining fiber 1120B. The first signal 1151A and the second signal 1151B (collectively referred to as signals 1151) from the modulators 1110 can have a first polarization state (e.g., TE, TM, etc.). The polarization maintaining fibers 1120A, 1120B prevent the polarization states of the signals 1151 from being distorted, thereby providing the waveguide amplifiers 1160A, 1160B (collectively referred to as 1160) with the signals 1151 having stable polarization states. The WDM filters 1140A, 1140B can combine a pump light (e.g., from the pump source 1130) into the signals 1151A, 1151B, respectively. For example, the WDM filters 1140A, 1140B can couple the pump light with the signals 1151A, 1151B, respectively.

The first signal 1151A can be amplified in the first waveguide amplifier 1160A, and the second signal 1151B can be amplified in the second waveguide amplifier 1160B. A pump light source 1130, optically coupled to the waveguide amplifiers 1160, can provide a pump light to the gain medium of the waveguide amplifiers 1160. In some examples, the waveguide amplifiers 1160 then can amplify the signals 1151, as discussed with respect to FIG. 1 to FIG. 9. For example, the waveguide amplifiers 1160 can receive a pump light (e.g., 115) from a light source (e.g., a VCSEL with a plurality of apertures) or a plurality of light sources (e.g., VCSELs) arranged along the waveguide amplifiers 1160. In some other examples, the waveguide amplifiers 1160 can receive a pump light in various ways. For example, as shown in FIG. 11, the waveguide amplifiers 1160 can receive a pump light from a pump light source 1130 that is optically coupled to an input portion of the waveguide amplifiers 1160.

Output portions of the waveguide amplifiers 1160 can be optically coupled to control components to control amplified signals. As shown, the waveguide amplifiers 1160 can be optically coupled to tunable filters 1166 (1166A, 1166B) and photo detectors 1162 (1162A, 1162B). The tunable filters 1166 may be substantially similar to or identical to the tunable filter 866, and the photo detectors 1162 may be substantially similar to or identical to the photo detector 862. That is, the tunable filters 1166 can filter the amplified signals at a wavelength, and the photo detectors 1162 can monitor the filtered signals. As shown, the first path (top) includes a first variable optical attenuator (VOA) 1168 to control a power level of the amplified (and/or filtered) signal.

Signals 1152A, 1152B (collectively revered to as 1152) that have been amplified and/or controlled (e.g., filtered, attenuated, etc.) can have a first polarization state (e.g., TE, TM, etc.). One of the signals 1152, for example, the signal 1152B, can be further controlled to change the polarization state of the signal 1152B. As shown, the second path (bottom) includes a polarization rotator 1170. The polarization rotator 1170 may be or include a faraday rotator, a birefringent rotator, a prism rotator, or any other materials or structures configured to rotate the polarization state of the signal 1152B. The polarization rotator 1170 can change the polarization state of the signal 1152B to a second polarization state (e.g., TM, TE, etc.) (the signal 1152B with a rotated polarization state referred to as 1152R).

A polarization beam splitter (PBS) 1172 can combine the signal 1152A and the signal 1152R into a signal 1153. That is, a first portion of the signal 1153 can have a first polarization (e.g., TE, from the first path (top)), and a second portion of the signal 1153 can have a second polarization (e.g., TM, from the second path (bottom)). The PBS 1172 can multiplex the signal 1152A having the first polarization state (e.g., TE) and the signal 1152R having the second polarization state (e.g., TM) thereby allowing for use of amplified signals having two orthogonal polarization states and doubling the bandwidth of the signals with a same symbol rate.

In some examples, the first and the second portions of the signal 1153 can be individually controlled by controlling the control components (e.g., the tunable filters 1166, the VOA 1168, etc.). For example, in the signal 1153, a power level of the first portion having the first polarization state can be independently controlled by controlling the VOA 1168. For example, in the signal 1153, a wavelength range of the second portion having the second polarization state can be independently controlled by controlling the tunable filter 1166B. The signal 1153 can be further controlled prior to outputting the signal 1155. For example, as shown, a VOA 1174 can be coupled to an output of the PBS 1172 to control a power level of the signal 1153.

As discussed, the apparatus 11 can multiplex signals having different polarization states. By individually controlling signals, the properties (e.g., power level, wavelength, etc.) of amplified signals having different polarization states can be controlled to be equal. This provides a solution to polarization dependent gain/loss of signals passing through optical components (e.g., waveguide amplifiers, etc.).

FIG. 12 illustrates a schematic view of an example apparatus 12 for amplifying light in accordance with various embodiments. More specifically, the apparatus 12 is an apparatus in which waveguide amplifiers (e.g., the apparatus 1, waveguide structures, EDWA, etc.) are optically coupled in parallel to multiplex two signals having different polarization states (e.g., output amplified lights in different polarization states). The apparatus 12 can receive an input signal 1250, amplify the input signal 1250, and output an output signal 1255 having more than one polarization states. As shown, the apparatus 12 includes a first path (top) including a first waveguide amplifier 1260A and a second path (bottom) including a second waveguide amplifier 1260B, and signals traveling each of the paths can be individually controlled to generate the output signal 1255.

The apparatus 12 includes a first modulator 1210A and a second modulator 1210B (collectively referred to as modulators 1210). The modulators 1210 may be or include an in-phase quadrature-phase (IQ) modulator configured to modulate and/or encode information on the input signal 1250. The first modulator 1210A can receive a first portion of the input signal 1250 and provide a first signal 1251A to the first waveguide amplifier 1260A (e.g., the apparatus 1, waveguide structures, EDWA, etc.). The second modulator 1210B can receive a second portion of the input signal 1250 and provide a second signal 1251B to the second waveguide amplifier 1260B (e.g., the apparatus 1, waveguide structures, EDWA, etc.), through a polarization rotator 1240. The polarization rotator 1240 can change a polarization state of the second signal 1251B (e.g., TE to TM). The second signal 1251B that passes through the polarization rotator 1240 is referred to as the second signal 1251R.

A first PBS 1220 can receive the first signal 1251A and the second signal 1251R (collectively referred to as the signals 1252). The first PBS 1220 can direct the signals 1252, through a polarization maintaining fiber, to a second PBS 1230. The second PBS 1220 can split the signals 1252 into a first signal 1253A having a first polarization state (e.g., TE) and a second signal 1253B having a second polarization state (e.g., TM). A second polarization rotator 1240, can change a polarization state of the second signal 1253B (e.g., TM to TE).

The first signal 1253A can be amplified in the first waveguide amplifier 1260A, and the second signal 1253B can be amplified in the second waveguide amplifier 1260B. A pump light source 1242, optically coupled to the waveguide amplifiers 1260A, 1260B, can provide a pump light to the gain medium of the waveguide amplifiers 1260A, 1260B. In some examples, the waveguide amplifiers 1260A, 1260B can amplify the signals 1253A, 1253B, as discussed with respect to FIG. 1 to FIG. 9. For example, the waveguide amplifiers 1260A, 1260B can receive a pump light (e.g., 115) from alight source (e.g., a VCSEL with a plurality of apertures) or a plurality of light sources (e.g., VCSELs) arranged along the waveguide amplifiers 1260A, 1260B. In some other examples, the waveguide amplifiers 1260A, 1260B can receive a pump light in various ways. For example, as shown in FIG. 12, the waveguide amplifiers 1260A, 1260B can receive a pump light from a pump light source 1242 that is optically coupled to an input portion of the waveguide amplifiers 1260A, 1260B.

Output portions of the waveguide amplifiers 1260A, 1260B can be optically coupled to control components to control amplified signals. As shown, the waveguide amplifiers 1260A, 1260B can be optically coupled to tunable filters and photo detectors. The tunable filters may be substantially similar to or identical to the tunable filter 866, and the photo detectors may be substantially similar to or identical to the photo detector 862. That is, the tunable filters can filter the amplified signals at a wavelength, and the photo detectors can monitor the filtered signals. As shown, the first path (top) includes a first variable optical attenuator (VOA) to control a power level of the amplified (and/or filtered) signal.

Signals 1252A, 1252B (collectively revered to as 1252) that have been amplified and/or controlled (e.g., filtered, attenuated, etc.) can have a first polarization state (e.g., TE, TM, etc.). One of the signals 1252, for example, the signal 1252B, can be further controlled to change the polarization state of the signal 1252B. As shown, the second path (bottom) includes a polarization rotator 1270. The polarization rotator 1270 may be or include a faraday rotator, a birefringent rotator, a prism rotator, or any other materials or structures configured to rotate the polarization state of the signal 1252B. The polarization rotator 1270 can change the polarization state of the signal 1252B to a second polarization state (e.g., TM, TE, etc.) (the signal 1252B with a rotated polarization state referred to as 1252R).

A polarization beam splitter (PBS) 1272 can combine the signal 1252A and the signal 1252R into a signal 1253. That is, a first portion of the signal 1253 can have a first polarization (e.g., TE, from the first path (top)), and a second portion of the signal 1253 can have a second polarization (e.g., TM, from the second path (bottom)). The PBS 1272 can multiplex the signal 1252A having the first polarization state (e.g., TE) and the signal 1252R having the second polarization state (e.g., TM) thereby allowing for use of amplified signals having two orthogonal polarization states and doubling the bandwidth of the signals with a same symbol rate.

In some examples, the first and the second portions of the signal 1253 can be individually controlled by controlling the control components (e.g., the tunable filters, the VOA, etc.). For example, in the signal 1253, a power level of the first portion having the first polarization state can be independently controlled by controlling the VOA in the first path (top). For example, in the signal 1253, a wavelength range of the second portion having the second polarization state can be independently controlled by controlling the tunable filter in the second path (bottom). The signal 1253 can be further controlled prior to outputting the signal 1255. For example, as shown, a VOA 1274 can be coupled to an output of the PBS 1272 to control a power level of the signal 1253.

As discussed, the apparatus 12 can multiplex signals having different polarization states. By individually controlling signals, the properties (e.g., power level, wavelength, etc.) of amplified signals having different polarization states can be controlled to be equal. This provides a solution to polarization dependent gain/loss of signals passing through optical components (e.g., waveguide amplifiers, etc.).

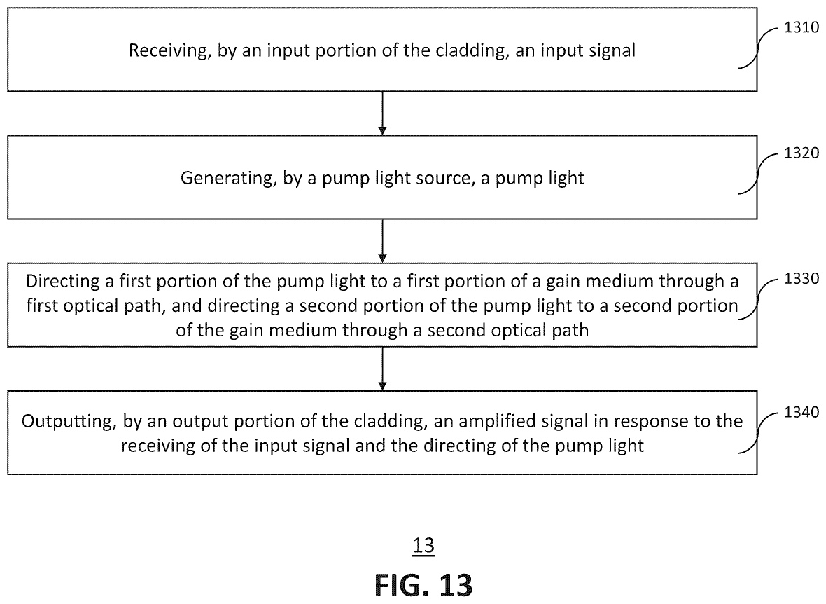

FIG. 13 is a flow chart of an example method 13 for amplifying light in accordance with various embodiments. The method 13 can be performed using any of the apparatus (e.g., the apparatus 1) discussed with respect to FIG. 1 to FIG. 12 or components thereof. For example, the method 13 can be performed using an apparatus (e.g., 1) including a substrate (e.g., 100), a cladding (e.g., 105) formed on the substrate, a first portion and a second portion of a gain medium (e.g., 110) formed inside the cladding, and a pump light source configured to provide a pump light (e.g., 115) through a plurality of optical paths (e.g., 117).

In brief overview, the method 13 can start with operation 1310 of receiving, by an input portion of the cladding, an input signal. The method 13 can continue to operation 1320 of generating, by a pump light source, a pump light. The method 13 can continue to operation 1330 of directing a first portion of the pump light to a first portion of a gain medium through a first optical path, and directing a second portion of the pump light to a second portion of the gain medium through a second optical path. The method 13 can continue to operation 1340 of outputting, by an output portion of the cladding, an amplified signal in response to the receiving of the input signal and the directing of the pump light. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments

The apparatus can receive an input signal through an input portion of the cladding (operation 1310). For example, the input portion of the cladding can be optically coupled to a light source that can provide the input signal.

In response to receipt of the input signal, a pump light source can generate a pump light (operation 1320). The pump light source may be one pump light source or a plurality of pump light sources. In some examples, the pump light source may be a vertical cavity surface emitting laser (VCSEL) integrated on a chip. In response to generation of the pump light, a first portion of the pump light can be directed to a first portion of a gain medium through a first optical path, and a second portion of the pump light can be directed to a second portion of the gain medium through a second optical path (operation 1330).

In some examples, the operation 1330 includes directing a pump light from a single light source into a gain medium through a plurality of optical paths. For example, the operation 1330 can include directing a first portion of the pump light into a first portion of the gain medium through a first optical path, and directing a second portion of the pump light into a second portion of the gain medium through a second optical path. In some examples, the operation 1330 includes directing a plurality of pump lights into a respective portion of the gain medium through a respective optical path. For example, the operation 1330 can include directing a first pump light into a first portion of the gain medium through a first optical path, and directing a second pump light into a second portion of the gain medium through a second optical path. In some examples, the light source can be integrated on a chip, and an aperture formed on the chip can define an optical path through which a pump light generated from the light source travel into a gain medium. In some examples, the operation 1330 can include directing a pump light using a grating coupler. For example, a plurality of pump lights can be directed to a plurality of portions of the gain medium through respective grating portions of the grating coupler. For example, a plurality of pump lights can be directed to a plurality of portions of the gain medium through respective grating couplers.

In response to the directing of a pump light, the gain medium can absorb the directed pump light and generate a light to amplify the input signal. For example, in response to receipt of the pump lights, the gain medium can spontaneously generate a light at the wavelength of the input signal.

In response to the receiving of the input signal and the directing of the pump light (and thus the amplifying of the input signal), an amplified signal is output through an output portion of the cladding (operation 1340).

The foregoing description of illustrative embodiments has been presented for purposes of illustration and of description. It is not intended to be exhaustive or limiting with respect to the precise form disclosed, and modifications and variations are possible in light of the above teachings or may be acquired from practice of the disclosed embodiments.

While certain embodiments have been illustrated and described, it should be understood that changes and modifications can be made therein in accordance with ordinary skill in the art without departing from the technology in its broader aspects as defined in the following claims.

The embodiments, illustratively described herein may suitably be practiced in the absence of any element or elements, limitation or limitations, not specifically disclosed herein. Thus, for example, the terms “comprising,” “including,” “containing,” etc. shall be read expansively and without limitation. Additionally, the terms and expressions employed herein have been used as terms of description and not of limitation, and there is no intention in the use of such terms and expressions of excluding any equivalents of the features shown and described or portions thereof, but it is recognized that various modifications are possible within the scope of the claimed technology. Additionally, the phrase “consisting essentially of” will be understood to include those elements specifically recited and those additional elements that do not materially affect the basic and novel characteristics of the claimed technology. The phrase “consisting of” excludes any element not specified.

The present disclosure is not to be limited in terms of the particular embodiments described in this application. Many modifications and variations can be made without departing from its spirit and scope, as will be apparent to those skilled in the art. Functionally equivalent methods and compositions within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds compositions or biological systems, which can of course vary. It is also to be understood that the terminology used herein is for the purpose of describing particular embodiments only, and is not intended to be limiting.

As will be understood by one skilled in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like, include the number recited and refer to ranges which can be subsequently broken down into subranges as discussed above. Finally, as will be understood by one skilled in the art, a range includes each individual member.

All publications, patent applications, issued patents, and other documents referred to in this specification are herein incorporated by reference as if each individual publication, patent application, issued patent, or other document was specifically and individually indicated to be incorporated by reference in its entirety. Definitions that are contained in text incorporated by reference are excluded to the extent that they contradict definitions in this disclosure.

Additional embodiments may be set forth in the following claims.

What is claimed is:

1. An apparatus for amplifying light, comprising:
a substrate;
a cladding formed on the substrate;
a gain medium formed inside the cladding;
a pump light source configured to provide a pump light through a plurality of optical paths;
wherein a first portion of the gain medium receives a first portion of the pump light through a first optical path, and a second portion of the gain medium receives a second portion of the pump light through a second optical path, the second optical path separate from the first optical path.

2. The apparatus of claim 1, further comprising:
an input portion of the cladding, the input portion configured to receive an input signal; and
an output portion of the cladding, the output portion configured to output an amplified signal in response to receipt of the input signal and the pump light.

3. The apparatus of claim 1, wherein the pump light source is a vertical cavity surface emitting laser (VCSEL).

4. The apparatus of claim 1, wherein the pump light source is integrated on a chip.

5. The apparatus of claim 4, further comprising:
a first aperture formed on the chip, the first aperture defining the first optical path; and
a second aperture formed on the chip, the second aperture defining the second optical path.

6. The apparatus of claim 1, further comprising:
a grating coupler optically coupled to the pump light source, the grating coupler comprising:
a first grating portion to direct the first portion of the pump light to the first portion of the gain medium through the first optical path; and
a second grating portion to direct the second portion of the pump light to the second portion of the gain medium through the second optical path.

7. The apparatus of claim 6, further comprising:
a waveguide structure to accommodate the cladding serving as a waveguide cladding and the gain medium serving as a waveguide core; and
a plurality of grating portions formed on the grating coupler, the plurality of grating portions including the first grating portion and the second grating portion,
wherein the plurality of grating portions are arranged such that each of the plurality of grating portions is to direct a corresponding portion of the pump light to one or more corresponding portions of the gain medium.

8. The apparatus of claim 7, wherein the gain medium is arranged in a spiral shape.

9. An apparatus for amplifying light, comprising:
a substrate;
a cladding formed on the substrate;
a gain medium formed inside the cladding;
a first pump light source disposed above a first portion the gain medium; and
a second pump light source disposed above a second portion of the gain medium, wherein
the first pump light source is configured to project a first pump light onto at least the first portion of the gain medium; and
the second pump light source is configured to project a second pump light onto at least the second portion of the gain medium.

10. The apparatus of claim 9, wherein the first pump light source and the second pump light source are integrated on a chip.

11. The apparatus of claim 9, wherein the first pump light source and the second pump light source are each a vertical cavity surface emitting laser (VCSEL).

12. The apparatus of claim 9, further comprising a reflective layer disposed above or below the gain medium.

13. The apparatus of claim 9, further comprising:
a waveguide structure to accommodate the cladding serving as a waveguide cladding and the gain medium serving as a waveguide core, wherein the gain medium is arranged within the cladding along the waveguide structure; and
a plurality of pump light sources, each configured to provide a corresponding pump light to a corresponding portion of the gain medium.

14. The apparatus of claim 9, wherein a first power level of the first pump light source is different from a second power level of the second pump light source.

15. The apparatus of claim 9, further comprising:
an input portion of the cladding, the input portion configured to receive an input signal; and
an output portion of the cladding, the output portion configured to output an amplified signal in response to receipt of the input signal and the pump light.

16. The apparatus of claim 15, further comprising at least one of:
a tunable filter configured to filter the amplified signal having a predetermined wavelength;
a photodetector to detect the amplified signal; or
an optical component configured to control a polarization state of the input signal or the amplified signal.

17. A method for amplifying light, comprising:
generating, by a pump light source, a pump light;
directing a first portion of the pump light to a first portion of a gain medium through a first optical path, and directing a second portion of the pump light to a second portion of the gain medium through a second optical path, wherein the first optical path and the second optical path are separate from each other,
wherein the gain medium is formed within a cladding of a substrate.

18. The method of claim 17, further comprising:
receiving, by an input portion of the cladding, an input signal; and
outputting, by an output portion of the cladding, an amplified signal in response to the receiving of the input signal and the directing of the pump light.

19. The method of claim 17, further comprising:
coupling the pump light to a grating coupler; and
directing, by a first grating portion of the grating coupler, the first portion of the pump light to the first portion of the gain medium through the first optical path, and directing, by a second grating portion of the grating coupler, the second portion of the pump light to the second portion of the gain medium through the second optical path.

20. The method of claim 17, wherein the pump light source is a vertical cavity surface emitting laser (VCSEL) integrated on a chip.
